(19) United States
(12) Patent Application Publication
(10) Pub. No.: US 2015/0364724 A1
(43) Pub. Date: Dec. 17, 2015

(54) Method for Producing an Organic Light-Emitting Component and Organic Light-Emitting Component

(71) Applicant: TECHNISCHE UNIVERSITÄT DRESDEN, Dresden (DE)

(72) Inventors: Yong Hyun Kim, Dresden (DE); Lars Mueller-Meskamp, Dresden (DE); Jonghee Lee, Dresden (DE); Simone Hofmann, Dresden (DE); Won Mok Kim, Seoul (KR); Karl Leo, Dresden (DE)

(73) Assignee: Technische Universitaet Dresden, Dresden (DE)

(21) Appl. No.: 14/652,183

(22) PCT Filed: Dec. 20, 2013
(86) PCT No.: PCT/DE2013/100436

§ 371 Date: Aug. 25, 2015

(30) Foreign Application Priority Data
Dec. 21, 2012 (DE) 10 2012 112 999.1

(51) Int. Cl. H01L 51/52; H01L 51/56

(52) U.S. Cl. CPC H01L 51/5268; H01L 51/56; H01L 2251/5369

(57) ABSTRACT

The invention relates to a method for producing an organic component having a layered arrangement, wherein the method includes the following steps: Preparing a substrate and producing a layer stack having an electrode, a counter electrode and organic layers with a light-emitting zone on the substrate, wherein the organic layers are produced between the electrode and the counter electrode, and in electrical contact with the electrode and the counter electrode, wherein the layer arrangement is produced with a light scattering functional layer containing metal oxide particles distributed randomly in two dimensions. The invention further relates to an organic light-emitting component having a layer arrangement.

The invention relates to a method for producing an organic light-emitting component with a layered arrangement, and an organic light-emitting component.

### BACKGROUND

Organic light-emitting components, particularly organic light-emitting diodes (OLED), are attracting more and more attention because of their potential as an efficient, inexpensive light source. An organic light-emitting component typically has a layered arrangement in which a layer stack with an electrode, a counter electrode and a stack of organic layers having a light-emitting zone is arranged on a substrate, wherein the layer stack is produced between the electrode and the counter electrode, and in electrical contact with the electrode and the counter electrode. When an electrical voltage is applied to both electrodes, charge carriers are injected into the stack of organic layers, and they recombine in the light-emitting zone, giving off light.

Attempts have been made to optimise the efficiency with which the light generated in the light-emitting zone is decoupled from the component. Such attempts include the provision of “light decoupling layers” on the component.

Such layers are often structured according to top-down methods, as in the case of the lithographically produced SiO2 structures by Sun et al. for decoupling guided modes (Sun et. al, Nature Photonics 2, 483-487 (2008)). Alternatively, “emergently” modulated surfaces as used, such as the nanofaceted surfaces of electron beam-vaporised MgO suggested by Hong et al. (Hong et al., Advanced Materials 22, 4890-4894 (2010)). Besides faceting, targeted buckling of the surface (A1 on PDMS) by layer voltages may also be used to decouple light (Koo et al., Nature Photonics 4, 222-226 (2010)). Such buckled surfaces may also be produced in photoresist using laser interference lithography (Mattersonet et al., Advanced Materials 13, 123-127 (2001)).

Another option is to use scattering particles, which can be integrated in the component as a layer with a matrix (Chang et al., Organic Electronics 13, 1073-1080 (2012), Nakamura et al., Optical review 13, 104-110 (2006)). Nakamura's approach is also noteworthy for the fact that an inverted scatter layer having a matrix with a high refractive index and scatter centres with a low refractive index is generated. Similar systems with a periodic arrangement and the photonic effects associated therewith may be achieved by applying silica microspheres (Yamasaki et al., Applied Physics Letters 76, 1243 (2000)). Photonic crystal systems, such as were produced by lithography and dry etching in the SiO2/SiNx system (Do et al., Advanced Materials 15, 1214-1218 (2003)) exhibit even greater organisation.

Besides these integrated approaches for decoupling, external approaches have also been devised, such applying a microlens array (Moller et al., Journal of applied physics 91, 3324 (2002)) or microlens films (Thomschke et al., Nano Letters (2012)).

Document DE 10 2008 048 161 A1 discloses an optoelectronic organic component. A layer with scattering particles that have been produced in advance and then mixed into a coating sol is formed by dip coating when the component's layer structure is created.

Document US 2008/0029147 A1 relates to an electrode for an electro-optical component. The electrode has a wetting layer consisting of an electrically conductive material on a substrate. A second layer of an electrically conductive material is produced on the wetting layer. The wetting layer has a first wetting property affecting the surface of the substrate. The second layer has a second wetting capability affecting the surface of the substrate. The wetting properties are different. The wetting layer changes an optical property of the electrode by virtue of its wetting capability.

Besides artificial decoupling structures, it has been suggested to adapt the refractive index by selection of appropriate materials. The organic light-emitting components are often prepared on a glass substrate, indium tin oxide (ITO) being used often as the electrode material. ITO electrodes strengthen the internal total reflection at the boundary between glass (n=1.5) and ITO (n=2.0). This has the effect of limiting the efficiency of light decoupling in conventional organic light-emitting component, which emit the light through the base electrode (bottom-emitting). The refractive index of the organic layer itself poses a further problem, since it also lies in the range (n=1.8-2). If a substrate with a high refractive index (n≧1.8) is used, the inner total reflection at the boundary between the glass and the ITO electrode is reduced significantly, and the light guided in the substrate can be emitted efficiently via decoupling structures on the surface. On the other hand, substrates with a high refractive index are not suitable for inexpensive mass production of OLEDs due to the high cost of the materials. Furthermore, in the absence of decoupling structures an undesirable total reflection occurs at the boundary between the air and the glass substrate, due to the large difference between the refractive indices.

Another attempt to improve decoupling envisages reducing the optical microcavity by using conductive polymer electrodes with a low refractive index. The use of oxide/metal/oxide electrodes which enable efficient decoupling due to their low layer thickness and modified thin film optics, represents a similar approach.

In view of the disadvantages and limitations described in the introduction, there is still a need to optimise light decoupling in organic light-emitting components, wherein some of the concepts described in the preceding might be combined with the scatter layers discussed here.

### SUMMARY

The object of the invention is to describe a method for producing an organic light-emitting component having a layered arrangement, and an organic light-emitting component, by which the light generated in the component may be decoupled more efficiently.

This object is solved according to the invention by a method for producing an organic light-emitting component having a layered arrangement as described in independent claim 1, and an organic light-emitting component having a layered arrangement as described in independent claim 12. Advantageous variations are the subject matter of dependent claims.

According to one aspect, a method for producing an organic light-emitting component having a layered arrangement is provided in which a substrate is prepared and a layer stack is produced on the substrate. The layer stack is produced on the substrate with an electrode, a counter electrode and organic layers with a light-emitting zone. In this context, the organic layers are formed between the electrode and the counter electrode and in electrical contact with the electrode and the counter electrode. The layered arrangement is produced with a light scattering functional layer that includes metal oxide particles distributed randomly in two dimensions.

According to a second aspect, an organic light-emitting component having a layered arrangement is provided. The layered arrangement includes a substrate and a layer stack arranged on the substrate. The layer stack comprises an electrode, a counter electrode and organic layers. The arrangement of organic layers includes a light-emitting zone which may be of monolayer or multilayer construction. The organic layers are arranged between the electrode and the counter electrode and are in electrical contact with the electrode and the counter electrode. The electrode may be a base electrode, which is then located closer to the substrate than the counter electrode, and the counter electrode serves as the covering electrode. The layered arrangement then has a light scattering functional layer formed with metal oxide particles distributed randomly in two dimensions.

The metal oxide particles may exist separately, that is to say at a distance from each other, or they may form a substantially closed layer. The metal oxide particles scatter the light generated in the component. The light scattering effect of the metal oxide particles may be based on a difference between the refractive index of the metal oxide particles and the refractive index of the material surrounding the metal oxide particles. The metal oxide particles may have the higher refractive index. However, a configuration may be envisaged in which the refractive index of the surrounding material is higher than the refractive index of the metal oxide particles. The difference between the refractive indices may be at least about 0.2. The material surrounding the metal oxide particles may be formed from one or more smoothing layers.

The layer stack may include one or more inorganic layers between the electrodes besides the organic layers, such as metallic or oxidic layers.

The electrodes may be of monolayer or multilayer construction, for example at least one of the electrodes may include one or more thin metal layers.

Besides the light-emitting zone, the stack of organic layers also comprises one or more transport layers, in the form of electron or hole transport layers. Provision may be made for electrical doping of the transport layers. In addition or alternatively thereto, transport layers may have the form of thin metal oxide layers.

During the construction of subsequent layers, the metal oxide particles that were produced previously on the layer below are embedded in the material of one or more following layers, that they are at least partly covered thereby. This finally results in a layer structure in which a hybrid layer is formed, containing the metal oxide particles, which may be arranged singly, and the material of the one or more subsequent layers, for example the material of one or more smoothing layers.

A preferred refinement provides that the light scattering functional layer is produced between the substrate and the electrode that forms a base electrode. In this embodiment, the functional layer together with one or more smoothing layers may optionally be arranged directly on the substrate, for example a glass substrate. In this or other embodiments, the functional layer may consist of tin oxide particles. It may be provided that the electrode serving as the base electrode in this context is applied directly to the functional layer or to the smoothing material that is optionally formed on top of that.

In an advantageous variant, it may be provided that the light scattering functional layer is formed between the electrode and the counter electrode. In this embodiment, the functional layer may be arranged in the stack of organic layers. The functional layer may be arranged between the two electrodes, above or below the light-emitting zone.

An advantageous embodiment provides that the light scattering functional layer is produced above the counter electrode that serves as a covering electrode. In this embodiment, the functional layer is located outside the arrangement with the electrode and counter electrode and the organic layer stack arranged therebetween. It may be provided that the functional layer is formed directly on the covering electrode. Alternatively, one or more intermediate layers may be arranged between the covering electrode and the functional layer. A component encapsulation may be provided above the functional layer, which is optionally provided with a smoothing material.

A development thereof preferably provides that the light scattering functional layer is formed on a side of the substrate facing away from the layer stack. In this embodiment, the functional layer is arranged on an underside of the substrate, which faces away from the layer stack. Light that passes through the substrate interacts with the functional layer.

In an advantageous variant, it may be provided that the metal oxide particles are in the form of metal oxide nanoclusters. The nanoclusters may have a size of about 10 nm to about several hundred nm.

In a refinement thereof, provision may be made to produce the functional layer as a light decoupling layer.

A preferred refinement provides that at least one smoothing layer is produced on the light scattering functional layer, in such manner that the at least one smoothing layer at least partly smoothes out protruding structures in the functional layer. The protruding structures are formed particularly by the metal oxide particles. These are then at least partly embedded by the smoothing layer. It may be provided that a smooth surface is provided for a subsequent layer in the layered arrangement by means of the smoothing material. The at least one smoothing layer may be a transparent layer, a polymer layer for example. The at least one smoothing layer may be formed with a thickness in the μm range. The at least one smoothing layer, which forms the surrounding material for the metal oxide particles, may have a refractive index from about 1.0 to about 1.9, preferably from about 1.2 to about 1.9 and more preferably from about 1.2 to about 1.7, relative in particular to the visible wavelength range. If the smoothing layer(s) is/are not provided, a surrounding material having a refractive index of this order may also be produced using the one or more following layers of the stack.

In one variant, the protruding structures may extend through all of the subsequent layers and cause layer unevenness (surface roughness) above the light scattering functional layer regardless of whether one or more smoothing layers are provided. This unevenness may extend as far as the covering layer, whether this is e.g. the covering electrode, a component encapsulation or another outer layer, affecting the intermediate layers to varying degrees.

In a practical variant, it may be provided that the layered arrangement includes at least one further functional layer, which is constructed with metal oxide particles distributed randomly in two dimensions. The notes provided in relation to the functional layer also apply correspondingly for the at least one further functional layer formed with metal oxide particles.

The one or more functional layers containing the metal oxide particles may be combined in the component with other functional layers, in particular also functional layers for implementing other light decoupling technologies.

It may be provided as part of the production process that in order to produce the light scattering functional layer a metal layer is deposited and is warmed in such manner that the metal oxide particles are formed in random distribution over the surface from the previously deposited metal layer. The warming or heating of the previously applied metal layer, which may be a layer of tin, for example, may be carried out in one or more stages.

It may be provided that a multistage tempering process comprising a tempering step in a vacuum and a subsequent tempering step in an air or oxygen environment is carried out when the light scattering functional layer is produced. For example, the metal layer deposited as a film may be warmed (heated) initially in a vacuum. During this stage, metal clusters may form. Following this either immediately or after some time has elapsed, a further treatment step for heating in an air or oxygen environment may be provided, particularly to oxidise the metal material. The deposited metal layer may be produced with a layer thickness from about 100 nm to about 500 nm. The single- or multistage warming results in the formation of the light scattering structure. It may also cause the conversion of the metal layer, preferably previously an uninterrupted layer, into individual particles located at a distance from each other. Alternative or additional porous nanostructures may also be formed.

Provision for one or more of the following steps may be made in conjunction with the production of the functional layer from the metal oxide particles. In particular, a smoothing layer may be applied after the functional layer is produced. In one step, a metal layer is deposited on the substrate, which may be a glass substrate, for example. In a following step, the compound structure consisting of substrate and metal layer is heated in a vacuum environment so that metal particles form. In a further step, the intermediate product is heated again, this time preferably in an air environment so that the metal particles are oxidised, forming metal oxide particles. In the step after this, a smoothing layer may be applied. In the process described, the smoothing layer is used to provide a smooth surface for the application of the following layer. Together, the metal oxide particles and the smoothing layer create a smoothed functional layer, on which the subsequent layer may be constructed. In the subsequent layer application, an electrode may be deposited on the smoothing layer.

The explanations provided with regard to the method for producing the organic light-emitting component also apply for the purpose of possible configurations of the component itself.

### DESCRIPTION OF EMBODIMENTS

In the following, further embodiments will be explained in greater detail with reference to the figures of a drawing. In the drawing:

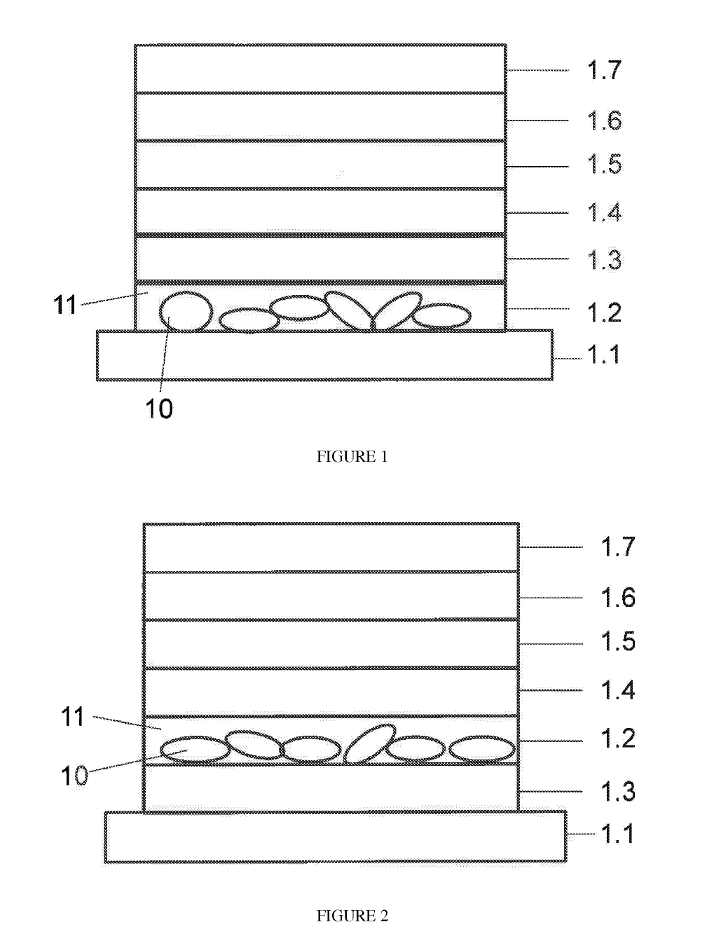

FIG. 1 is a diagrammatic representation of a layered arrangement for an organic light-emitting component having a smoothed functional layer which is arranged between a substrate and a base electrode,

FIG. 2 is a diagrammatic representation of a layered arrangement for an organic light-emitting component, in which the smoothed functional layer is arranged between the base electrode and the covering electrode,

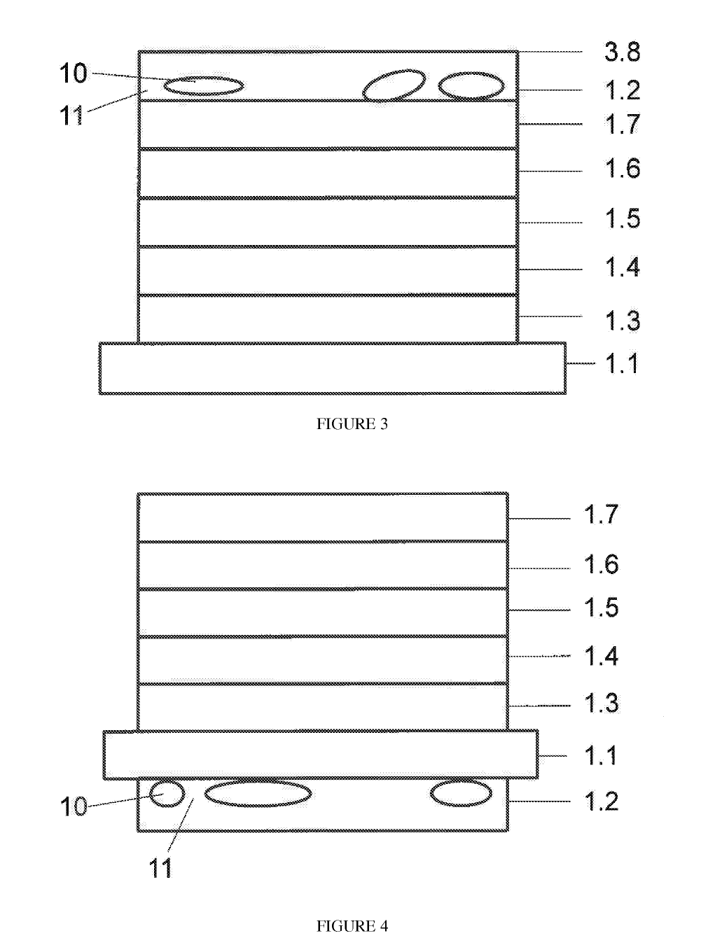

FIG. 3 is a diagrammatic representation of a layered arrangement for an organic light-emitting component, in which the smoothed functional layer is arranged on the covering electrode,

FIG. 4 is a diagrammatic representation of a layered arrangement for an organic light-emitting component, in which the smoothed functional layer is arranged on an underside of the substrate,

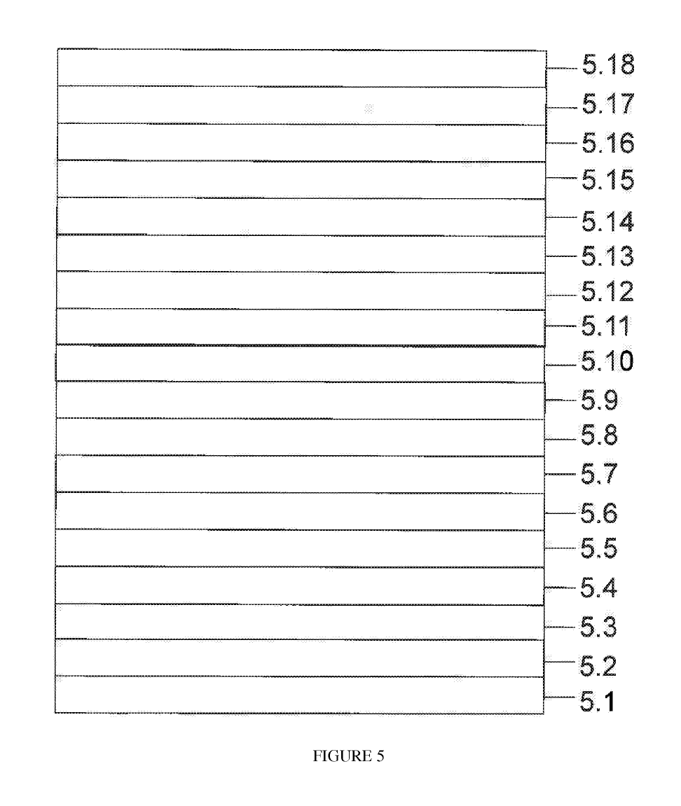

FIG. 5 is a diagrammatic representation of a layered arrangement for an organic light-emitting component,

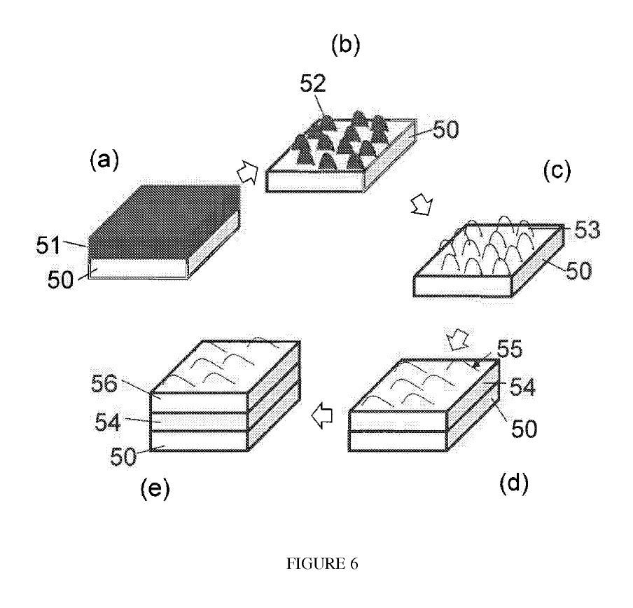

FIG. 6 is a diagrammatic representation of the production of a functional layer with separate metal oxide particles,

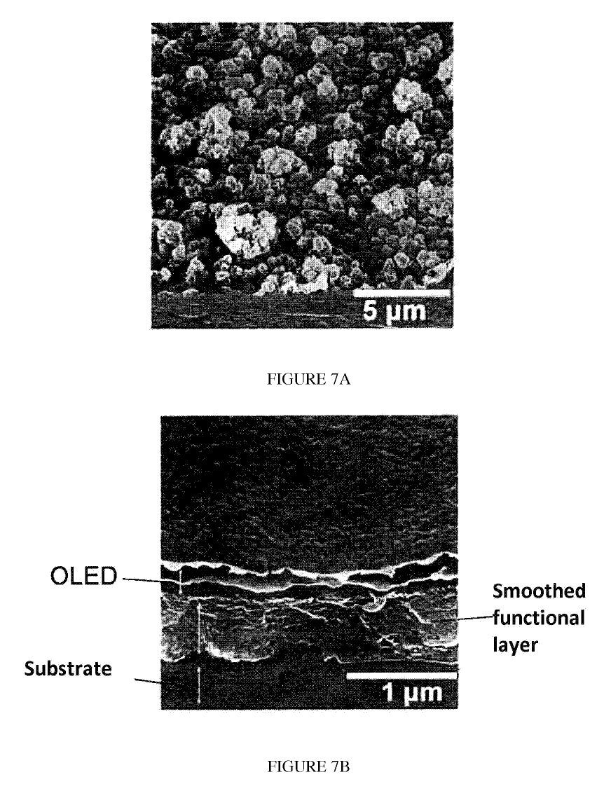

FIGS. 7A and 7B shows experimental results from AFM and SEM examinations,

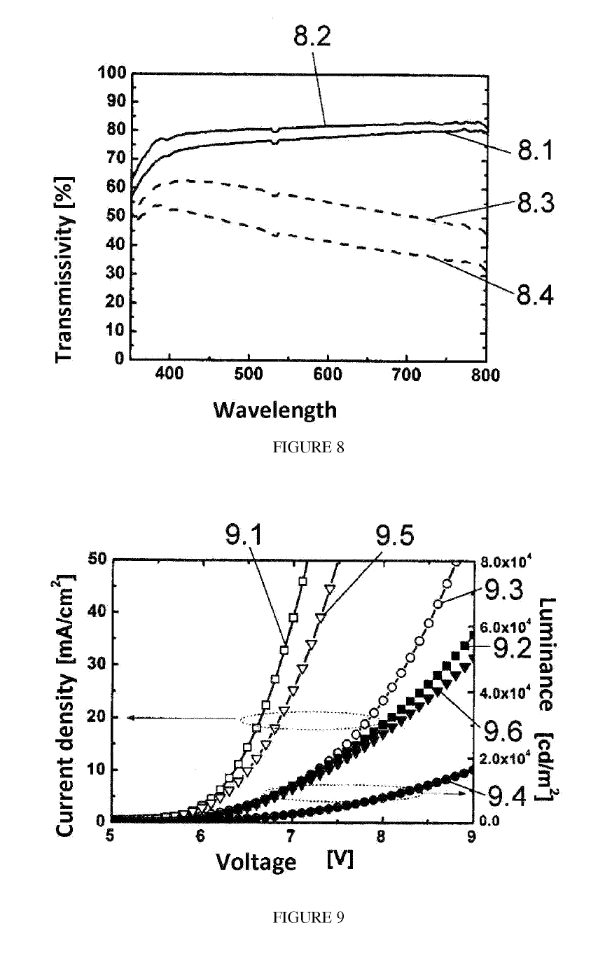

FIG. 8 is a graphical representation of transmittance as a function of wavelength for a functional layer system,

FIG. 9 is a graphical representation of current density as a function of voltage for organic light-emitting components with a light scattering functional layer,

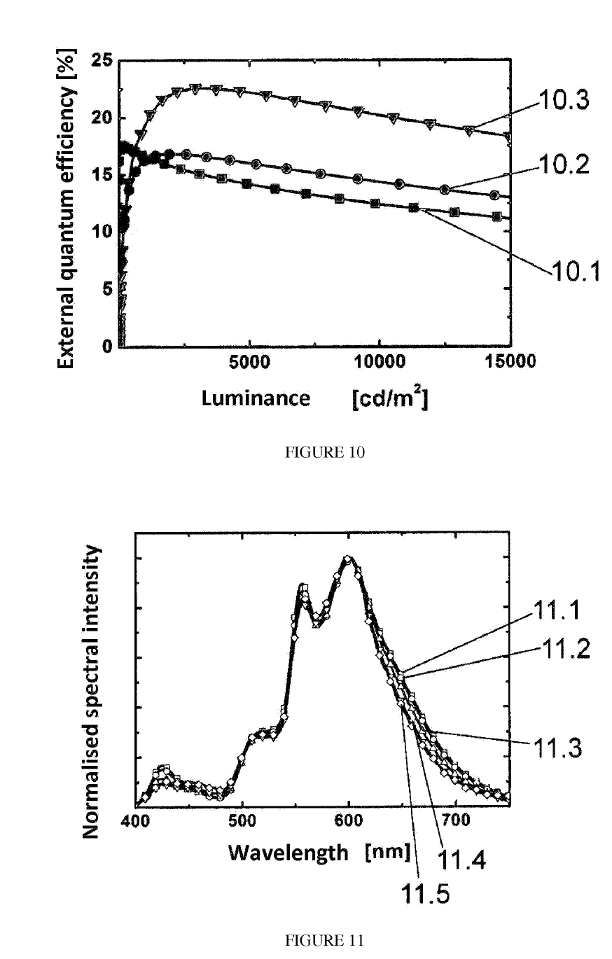

FIG. 10 is a graphical representation of external quantum efficiency as a function of luminance for organic light-emitting components with a light scattering functional layer,

FIG. 11 is a graphical representation of normalised spectral intensity as a function of wave-length from various viewing angles for an organic light-emitting component with a light scattering functional layer,

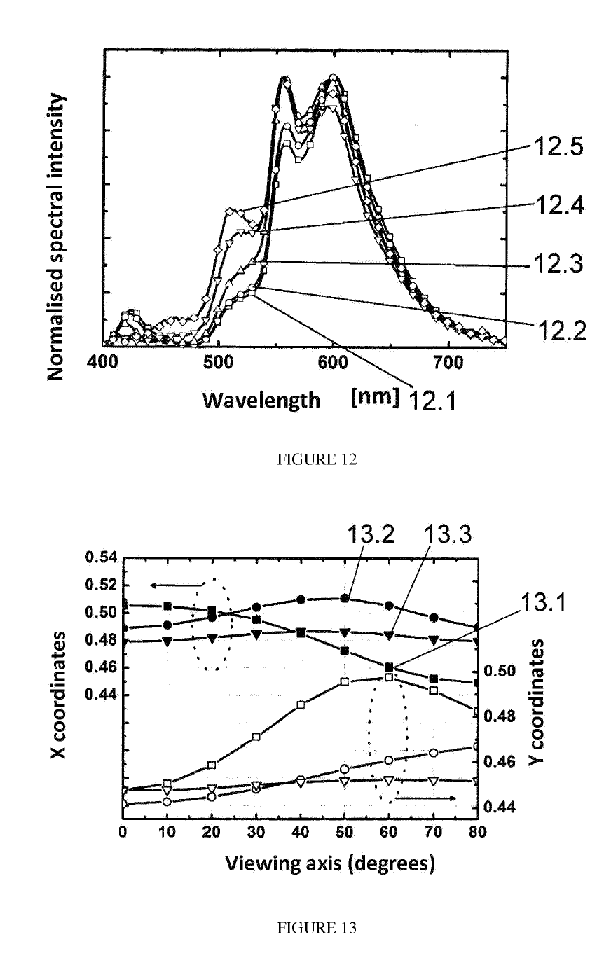

FIG. 12 is a graphical representation of normalised spectral intensity as a function of wave-length from various viewing angles for an organic light-emitting component without a light scattering functional layer (reference),

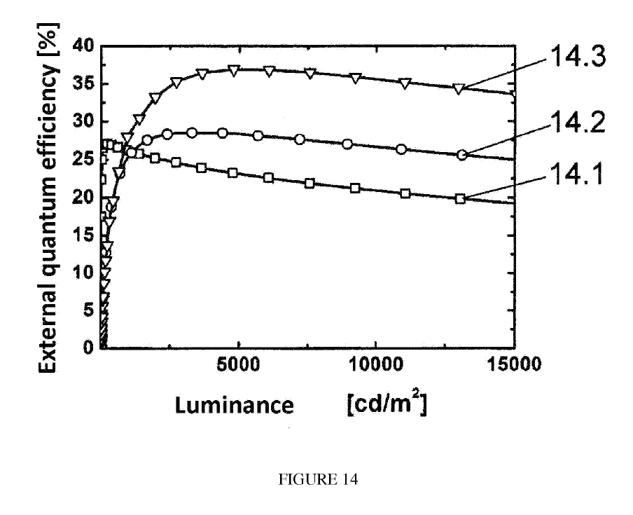

FIG. 13 is a graphical CIE representation of various organic light-emitting components with and without a light scattering functional layer, and

FIG. 14 shows experimental results for external quantum efficiency as a function of luminance with the application of a hemispherical lens on the glass substrate for the various organic light-emitting components of FIG. 13.

FIG. 1 is a diagrammatic representation of a layered arrangement for an organic light-emitting component, for example an organic light emitting diode (OLED), having a smoothed functional layer 1.2 which is arranged between a substrate 1.1 and a base electrode 1.3. Smoothed functional layer 1.2 forms a layer system and contains single metal oxide particles 10 in a layer material of a smoothing layer 11. In the example shown, an organic light emitting diode having a base electrode 1.3, a first charge carrier transport layer 1.4, a light-emitting zone 1.5, a second charge carrier transport layer 1.6 and a covering electrode 1.7 is applied to smoothed functional layer 1.2.

FIG. 2 is a diagrammatic representation of a layered arrangement for an organic light-emitting component, in which smoothed functional layer 1.2 is arranged between base electrode 1.3 and covering electrode 1.7, that is to say in the stack of organic layers 1.4 to 1.6.

FIG. 3 is a diagrammatic representation of a layered arrangement for an organic light-emitting component, in which smoothed functional layer 1.2 is arranged on covering electrode 1.7.

FIG. 4 is a diagrammatic representation of a layered arrangement for an organic light-emitting component, in which smoothed functional layer 1.2 is arranged on an underside 12 of substrate 1.1.

FIG. 5 is a diagrammatic representation of a layered arrangement for an organic, white light-emitting component for which the following structure was chosen:
5.1: Glass substrate
5.2: Light scattering layer with metal oxide particles
5.3: Smoothing layer
5.4: Poly(3,4-ethylenedioxythiophene):poly(styrene sulfonate) (PEDOT:PSS) (layer thickness: 58 nm)
5.5: (N,N,N′,N′-tetrakis(4-methoxyphenyl)-benzidine) (MeO-TPD): -(perfluoronaphthalene-2,6-diylidene)dimalononitrile (F6-TCNNQ) (2% by wt.) (35 nm)
5.6: 2,2′,7,7′-tetrakis-(N,N′-diphenylamino)-9,9′-spirobifluorene (Spiro-TAD) (10 nm)
5.7: N,N′-di-1-naphthalenyl-N,N′-diphenyl-[1,1′:4′,1″:4″,1′″-Quaterphenyl]-4,4′″-diamine (4P-NPD):Iridium(III)bis(2-methyldibenzo-[f,h]quinoxaline)(acetylacetonate) (Ir(MDQ)₂(acac)) (5% by wt.) (5 nm)
5.8: 4P-NPD (3 nm)
5.9: 4,7-diphenyl-1,10-phenanthroline (BPhen) (layer thickness: 10 nm)
5.10: BPhen:Cs (1:1) (90 nm)
5.11: Ag (0.5 nm)
5.12: MeO-TPD:F6-TCNNQ (2% by wt.) (75 nm)
5.13: Spiro-TAD (10 nm)
5.14: 4,4′,4″ tris(N-carbazolyl)-triphenylamine (TCTA):fac-tris(2-phenylpyridine) iridium(III) (Ir(ppy)₃):bis(2-(9,9-dihexylfluorenyl)-1-pyridine) (acetyl acetonate) iridium(III) (Ir(dhfpy)₂(acac)) (91:8:1% by wt.) (5 nm)
5.15: 2,2′2″-(1,3,5-benzenetriyl)-tris[1-phenyl-1H-benzimidazole] (TPBI):Ir(ppy)3:Ir(dhfpy)2(acac) (91:8:1% by wt.) (5 nm)
5.16: TPBI (10 nm)
5.17: BPhen:Cs (1:1) (60 nm)
5.18: Al (100 nm)

The OLED shown as exemplary embodiment in FIG. 5 consists of the following functional units: substrate (5.1), light scattering metal oxide particle layer (5.2), smoothing layer (5.3), polymer electrode (5.4). A “triplet harvesting unit” for red/blue emission consisting of a hole transport layer (5.5), an electron blocking layer (5.6), an emitter layer (5.7) with a red emitter in the matrix, a further emitter layer (5.8) with a blue emitter, a blocking layer (5.9) and a transport layer (5.10) is applied on top of this. This is followed by a yellow/green emitting unit (5.14/5.15) with the corresponding transport and blocking layers. An opaque metal layer (5.18) is used as the covering electrode.

To produce the organic light-emitting component, a metal film of tin having a thickness of 300 nm was deposited by sputtering on a glass substrate at room temperature. The metal film was then heated in a vacuum environment (10⁻³ mbar) at 300° C. for 30 min. In a further step, the film was then heated in an air environment at 500° C. for 1 hr. The layer thus obtained of single tin oxide particles distributed randomly over the surface of the glass substrate was then covered with a smoothing layer made from a polymer material. For this, a photoresist (on a propylene glycol monomethyl ether acetate base) was used. The film layer thus obtained was warmed on a hot plate at 130° C. for 10 min. PEDOT:PSS with 6% by vol. ethylene glycol was applied by spin-coating as the material for the conducting electrode. The layer stack was baked at 120° C. for 15 min.

Transmissivity was examined with a spectrometer. Atomic force microscopy (AFM) readings were also recorded. Scanning electron microscope (SEM) images were also recorded.

Then, an organic light-emitting diode was placed on the layer system prepared in this way, which in this respect provides a smoothed functional layer with the metal oxide particles. In this process, the organic layers were deposited by thermal vaporisation in a vacuum environment. The component was heated at 110° C. for 120 min in a vacuum chamber immediately before the organic layers were deposited in order to remove residual water from the PEDOT:PSS electrode. After the layers of the organic light-emitting component had been deposited, they were encapsulated with a covering glass.

FIG. 6 is a diagrammatic representation relating to the production of the functional layer of the metal oxide particles on a substrate and subsequent application of a smoothing layer. In one step (a), a metal layer 51 is deposited on substrate 50, which may be a glass substrate, for example. In a following step (b), the compound structure of substrate 50 and metal layer 51 is heated in a vacuum environment, so that metal particles 52 are formed. In a further step (c), the intermediate product is heated again, this time in an air environment, so that the metal particles 52 are oxidised, forming metal oxide particles 53. In the next step (d), a smoothing layer 54 is applied. In the method shown, a smooth surface 55 is provided with the aid of smoothing layer 54 for the subsequent layer application. Together, the metal oxide particles 53 and the smoothing layer 54 create a smoothed functional layer as a basis for constructing the subsequent layers. In this layer application, an electrode 56 is then deposited on smoothing layer 54 according to step (e) in the example shown.

FIG. 8 shows a graphical representation of relative transmittance as a function of wavelength for a layer system constructed in said manner with a substrate, metal oxide particles and a smoothing layer, and an embodiment in which the smoothing layer is not present. Upper curves 8.1 and 8.2 relate to total transmissivity, while lower curves 8.3 and 8.4 related to the diffuse component of the transmitting capability. Curves 8.1 and 8.3 show the results for the layer construction without a smoothing layer (substrate and metal oxide particles located thereon). Curves 8.2 and 8.4 relate to the layer construction with a substrate, metal oxide particles and smoothing layer.

FIG. 7 shows results from SEM measurements. FIG. 7A shows the functional layer with the metal oxide particles and without a smoothing layer. FIG. 7B shows the layered arrangement in which the smoothed functional layer with metal oxide particles and a white light-emitting organic light emitting diode are arranged on the glass substrate.

Other organic light emitting components were produced. For these, the layer structure according to FIG. 5 was selected in all cases.

For comparison purposes, a reference component was produced in which the base electrode consists of ITO (reference 1). This component also did not include the light scattering functional layer 5.2. Another layer structure was selected for a further reference component (reference 2), in which the light scattering functional layer 5.2 was also missing, wherein a PEDOT:PSS electrode is used.

FIGS. 9 to 12 show experimental results for the three different organic light emitting components.

In FIG. 9, curves 9.1 and 9.2 relate to the component according to reference 1. Curves 9.3 and 9.4 relate to the component according to reference 2. Curves 9.5 and 9.6 relate to the component according to FIG. 5.

In FIG. 10, curve 10.1 relates to the component according to reference 1. Curve 10.2 relates to the component according to reference 2. Finally, curve 10.3 shows the results for the component according to FIG. 5. It is evident that the use of the functional layer in the component according to FIG. 5 enables considerable improvement in external quantum efficiency compared with the other references.

FIG. 11 shows a graphical representation of normalised spectral intensity from various viewing angles for the component according to FIG. 5. It is evident that only very small shifts occur depending on the viewing angle. This is not true for the reference component of reference 1 according to FIG. 12.

In FIG. 13, the shift of the colour point is plotted against the angle for the three components. Curve 13.1 relates to the component according to reference 1. Curve 13.2 relates to the component according to reference 2. Finally, curve 13.3 shows the results for the component according to FIG. 5, which exhibits significantly more stable colour coordinates.

Experiments were also carried out to investigate the effects of a hemispherical lens on measurements of the component, in order to pursue the question of the potential of the technology. FIG. 14 shows experimental results for external quantum efficiency (EQE) as a function of luminance (cd/m²) when a hemispherical lens is used on the glass substrate. Curve 14.1 relates to the component according to reference 1, whereas curve 14.2 relates to the component according to reference 2. Curve 14.3 shows the results for the component according to FIG. 5.

The following table summarises the results of comparing the measurements with and without a hemispherical lens.

| | Without lens | | | With lens | | |
|---|---|---|---|---|---|---|
| | | | EQE | | | EQE |
| @10000 cd/m² | lm/W | EQE | increase | lm/W | EQE | increase |
| Reference 1 | 14.5 | 12.3 | x | 25.4 | 20.8 | 1.8 |
| Reference 2 | 13.1 | 14.3 | 1.2 | 26.1 | 26.6 | 2.2 |
| FIG. 5 | 22.7 | 20.3 | 1.7 | 41.6 | 35.6 | 2.9 |

The features of the invention disclosed in the preceding description, and in the claims and the drawing, may be significant either individually or in any combination for the realisation of the invention in the different variations thereof.

1. A method for producing an organic component having a layered arrangement, wherein the method includes the following steps:
providing a substrate; and
arranging a layer stack on the substrate, the layer stack comprising an electrode, a counter electrode, and organic layers having a light-emitting zone, wherein the organic layers are disposed between the electrode and the counter electrode, and in electrical contact with the electrode and the counter electrode, and wherein the layer arrangement further comprises a light scattering functional layer comprising metal oxide particles distributed randomly in two dimensions.

2. The method according to claim 1, wherein the light scattering functional layer is disposed between the substrate and whichever of the electrode and the counter electrode that functions as a base electrode.

3. The method according to claim 1, wherein the light scattering functional layer is disposed between the electrode and the counter electrode.

4. The method according to claim 1, wherein the light scattering functional layer is disposed the counter electrode, which functions as a covering electrode.

5. The method according to claim 1, wherein the light scattering functional layer is disposed on a side of the substrate that is opposite the layer stack.

6. The method according to claim 1, wherein the metal oxide particles comprise metal oxide nanoclusters.

7. The method according to claim 1, wherein the light scattering functional layer is a light decoupling layer.

8. The method according to claim 1, wherein at least one smoothing layer is disposed on the light scattering functional layer such that protruding structures of the light scattering functional layer are at least partially smoothed by the at least one smoothing layer.

9. The method according to claim 1, wherein the layer arrangement further comprises at least one additional light scattering functional layer, which comprises metal oxide particles distributed randomly in two dimensions.

10. The method according to claim 1, wherein the light scattering functional layer is formed, in part, by heating a metal layer, the steps comprising:
depositing a metal layer;
heating the metal layer to a temperature sufficient to form the single metal oxide particles distributed randomly in two dimensions.

11. The method according to claim 10, wherein the method further comprises a first tempering step in a vacuum and a second tempering step in an air or oxygen environment.

12. An organic light-emitting component having a layer arrangement, wherein the layer arrangement includes:
a substrate; and
a layer stack arranged on the substrate, the layer stack comprising an electrode, a counter electrode, and a stack of organic layers including a light-emitting zone, wherein the stack is disposed between the electrode and the counter electrode, and is in contact with the electrode and the counter electrode, and wherein the layer arrangement comprises a light scattering functional layer comprising metal oxide particles distributed randomly in two dimensions.
